(19) United States
(12) Patent Application Publication
(10) Pub. No.: US 2026/0135397 A1
(43) Pub. Date: May 14, 2026

(54) DEVICE AND METHOD FOR CHARGING BATTERY

(71) Applicants: HYUNDAI MOTOR COMPANY, Seoul (KR); KIA CORPORATION, Seoul (KR)

(72) Inventor: Hyeon Myeong Kim, Hwaseong-si (KR)

(73) Assignees: HYUNDAI MOTOR COMPANY, Seoul (KR); KIA CORPORATION, Seoul (KR)

(21) Appl. No.: 19/203,791

(22) Filed: May 9, 2025

(30) Foreign Application Priority Data
Nov. 8, 2024 (KR) 10-2024-0157636

(51) Int. Cl. H02J 7/00; B60L 53/60; G01R 19/165

(52) U.S. Cl. CPC H02J 7/60; G01R 19/16576; H02J 7/80; B60L 53/60

(57) ABSTRACT

A device for charging a battery is provided. The device includes a power input terminal including a plurality of alternating current (AC) power lines, a neutral line, and a ground line, a voltage detection unit detecting a voltage between the neutral line and the ground line and outputting a detection voltage, and a control unit determining whether the voltage between the neutral line and the ground line is abnormal based on the detection voltage, and controlling a predetermined operation when the voltage is determined to be abnormal.

### CROSS-REFERENCE TO RELATED APPLICATION(S)

This application claims benefit of priority to Korean Patent Application No. 10-2024-0157636 filed on Nov. 8, 2024 in the Korean Intellectual Property Office, the disclosure of which is incorporated herein by reference in its entirety.

### TECHNICAL FIELD

The present disclosure relates to a device and method for charging a battery, which may be applied to an electric vehicle (EV) battery.

### BACKGROUND

In general, electric vehicles (EVs) include rechargeable batteries, and to charge these batteries, a charging device (for example, a slow charger) converting AC power into an AC voltage suitable for charging the battery is used.

In a typical charging device, the voltage between the neutral line on the input power side and the ground may be close to or almost zero voltage in some (e.g., normal) cases.

However, in an environment in which power quality or grounding is poor, an (e.g., abnormal) voltage exceeding the reference voltage may occur between the neutral line and the ground due to poor grounding or voltage imbalance.

However, some existing battery charging devices cannot measure the voltage between the neutral line (N) on the input power side and the ground (Earth), so when an abnormal voltage occurs between the neutral line and the ground, the voltage cannot be measured by the measuring device, and therefore there may be a problem in that it cannot respond appropriately thereto.

### SUMMARY

An aspect of the present disclosure is to provide a device and method for charging a battery in which a voltage between a neutral line on an input power supply side and ground may be detected and a predetermined operation may be controlled based on the detected voltage when an abnormal voltage occurs between the neutral line and the ground.

According to an aspect of the present disclosure, a device for charging a battery includes a power input terminal including a plurality of alternating current (AC) power lines, a neutral line, and a ground line, a voltage detection unit detecting a voltage between the neutral line and the ground line and outputting a detection voltage, and a control unit determining whether the voltage between the neutral line and the ground line is abnormal based on the detection voltage, and controlling a predetermined operation when the voltage is determined to be abnormal.

The control unit is configured to include an abnormal voltage determination unit determining whether the voltage between the neutral line and the ground line is an abnormal voltage based on the detection voltage, and an operation control unit controlling the predetermined operation when the voltage between the neutral line and the ground line is determined to be an abnormal voltage.

The abnormal voltage determination unit is configured to include a first comparison unit comparing the detection voltage with a first reference voltage and outputting a first comparison signal having a level depending on whether the detection voltage exceeds the first reference voltage.

The operation control unit is configured to include a first control logic unit performing a first control controlling output control for charging and an abnormality occurrence alarm when a current charging operation is on, and controlling an alarm when the current charging operation is off, when an occurrence of a first-stage abnormality is determined based on the first comparison signal.

The device for charging a battery is configured to further include an output control unit controlling a charging current according to the first control of the first control logic unit, and an alarm output unit outputting the abnormality occurrence alarm notifying the occurrence of the first-stage abnormality according to the first control of the first control logic unit.

The abnormal voltage determination unit is configured to include a first comparison unit comparing the detection voltage with a first reference voltage and outputting a first comparison signal having a level depending on whether the detection voltage exceeds the first reference voltage, and a second comparison unit comparing the detection voltage with a second reference voltage when the detection voltage exceeds the first reference voltage and outputting a second comparison signal having a level depending on whether the detection voltage exceeds the second reference voltage.

The operation control unit is configured to include a second control logic unit of, when an occurrence of a first-stage abnormality is determined based on the first comparison signal and the second comparison signal, performing a first control of controlling output control and an abnormality occurrence alarm when a current charging operation is on, and controlling an alarm when the current charging operation is off, and when an occurrence of a second-stage abnormality is determined based on the first comparison signal and the second comparison signal, performing a second control of controlling stopping of a charging operation when the current charging operation is on, and controlling an unusable alarm when the current charging operation is off.

The device for charging a battery is configured to further include a power switch switching a power line connected to the power input terminal to an off state according to the second control of the second control logic unit, an output control unit controlling a charging current according to the second control of the second control logic unit, and an alarm output unit outputting an unusable alarm notifying the occurrence of the second-stage abnormality according to the second control of the second control logic unit.

According to an aspect of the present disclosure, a method of charging a battery includes a voltage detection operation of detecting a voltage between a ground line and a neutral line included in a power input terminal for receiving AC power using a plurality of AC power lines and the neutral line, and generating a detection voltage, a detection voltage receiving operation of receiving the detection voltage from a voltage detection unit, and a control operation of determining whether the voltage between the neutral line and the ground line is abnormal based on the detection voltage, and controlling a predetermined operation when the voltage is determined to be abnormal.

The control operation is configured to include an abnormal voltage determination operation of determining whether the voltage between the neutral line and the ground line is an abnormal voltage based on the detection voltage, and an operation control operation of controlling a predetermined operation when the voltage between the neutral line and the ground line is determined to be the abnormal voltage.

The abnormal voltage determination operation is configured to include a first comparison operation of comparing the detection voltage with a first reference voltage and outputting a first comparison signal having a level depending on whether the detection voltage exceeds the first reference voltage.

The operation control operation is configured to include a first control operation of performing a first control when an occurrence of a first-stage abnormality is determined based on the first comparison signal, controlling output control and an abnormality occurrence alarm when a current charging operation is on, and controlling an alarm when the current charging operation is off.

The abnormal voltage determination operation is configured to include the first comparison operation of comparing the detection voltage with the first reference voltage and outputting the first comparison signal having a level depending on whether the detection voltage exceeds the first reference voltage, and a second comparison operation of comparing the detection voltage with a second reference voltage and outputting a second comparison signal having a level depending on whether the detection voltage exceeds the second reference voltage, when the detection voltage exceeds the first reference voltage.

The operation control operation is configured to include a first control operation of performing a first control for controlling output control and an abnormality occurrence alarm when a current charging operation is on and controlling an alarm when the current charging operation is off, when an occurrence of a first-stage abnormality is determined based on the first comparison signal and the second comparison signal, and a second control operation of performing a second control for controlling stopping a charging operation when the current charging operation is on, and controlling an unusable alarm when the current charging operation is off, when an occurrence of a second-stage abnormality is determined based on the first comparison signal and the second comparison signal.

In addition, the aspect of the present disclosure is not limited to the aspect illustrated above, and other aspects may be additionally provided in the process described below.

### BRIEF DESCRIPTION OF DRAWINGS

The above and other aspects, features, and advantages of the present disclosure will be more clearly understood from the following detailed description, taken in conjunction with the accompanying drawings.

FIG. 1 is an example diagram of a device for charging a battery according to an embodiment.

FIG. 2 is a user explanation diagram of a device for charging a battery.

FIG. 3 is an example diagram of a control unit.

FIG. 4 is an example diagram of abnormal voltage determination.

FIG. 5 is an example diagram of an operation control unit.

FIG. 6 is an example diagram of an output control unit and an alarm output unit.

FIG. 7 is an example diagram of an abnormal voltage determination unit.

FIG. 8 is an example diagram of an operation control unit.

FIG. 9 is another example diagram of an output control unit and an alarm output unit.

FIG. 10 is a flowchart illustrating a method of charging a battery according to an embodiment.

FIG. 11 is an example diagram of a control operation.

FIG. 12 is an example diagram of an abnormal voltage determination operation.

FIG. 13 is an example diagram of an operation control operation.

FIG. 14 is an example diagram of an abnormal voltage determination operation.

FIG. 15 is an example diagram of an operation control operation.

In the drawings and detailed descriptions, the same reference numerals refer to the same components. The drawings may not be to scale, and the relative sizes, proportions, and depictions of drawing elements may be exaggerated for clarity, explanation, and convenience.

### DETAILED DESCRIPTION

Herein, detailed embodiments will be described with reference to the drawings. The detailed description below is provided to facilitate an understanding of the methods, devices, and/or systems described herein. However, this disclosure provides examples and the present disclosure is not limited thereto.

In describing embodiments, detailed descriptions of various technologies related to the present disclosure may be omitted if it is determined that such detailed descriptions may obscure the gist of the present disclosure. The terms described below are provided in consideration of the functions in the present disclosure, and may vary depending on the intention (e.g., or custom) of the user or operator. Therefore, the meaning of the terms should be made based on the contents throughout this specification. The terminology used in the detailed description is for describing embodiments and should not be limiting. Unless stated otherwise, expressions in the singular form include the meaning in the plural form. In this description, expressions such as “including” or “provided” are intended to indicate features, numbers, operations, operations, elements, parts or combinations thereof, and it should not be construed to exclude the existence or possibility of one or more other features, numbers, operations, operations, elements, or parts or combinations thereof, other than those described.

Hereinafter, embodiments will be described in more detail with reference to the attached drawings.

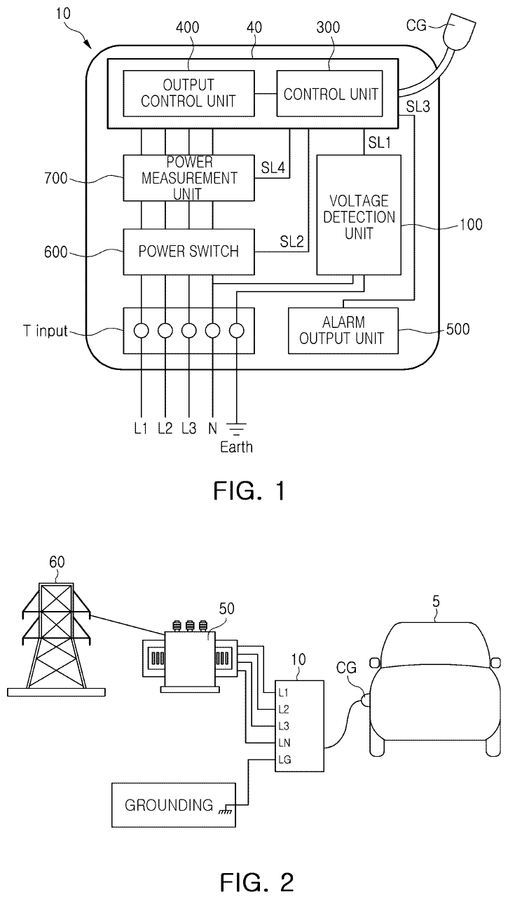

FIG. 1 is an example diagram of a device for charging a battery according to an embodiment.

Referring to FIG. 1, a device 10 for charging a battery according to an embodiment may include a power input terminal Tinput, a voltage detection unit 100, and a control unit 300.

The power input terminal Tinput may include a plurality of alternating current (AC) power lines L1, L2 and L3 for receiving AC power from a transformer or the like, a neutral line LN (e.g., N on FIG. 1), and a ground line LG connected to the ground (e.g., Earth on FIG. 1). For example, in the case of a three-phase AC power source, the AC power lines L1, L2 and L3 of the power input terminal Tinput may be a u-phase line, a v-phase line, and a w-phase line.

The voltage detection unit 100 may detect a voltage between a neutral line LN and a ground line LG included in the power input terminal Tinput and output a detection voltage Vd. For example, the voltage detection unit 100 may include a detection resistor for detecting the voltage between the neutral line LN and the ground line LG. The above example is an example for explanation and understanding, and is not limited thereto. When the detection resistor is used as in the above example, if a current flows through the detection resistor due to the voltage between the neutral line LN and the ground line LG, the detection voltage may be measured. For example, the voltage detection unit 100 may be connected to the control unit 300 through a first signal line SL1 for transmitting the detection voltage Vd.

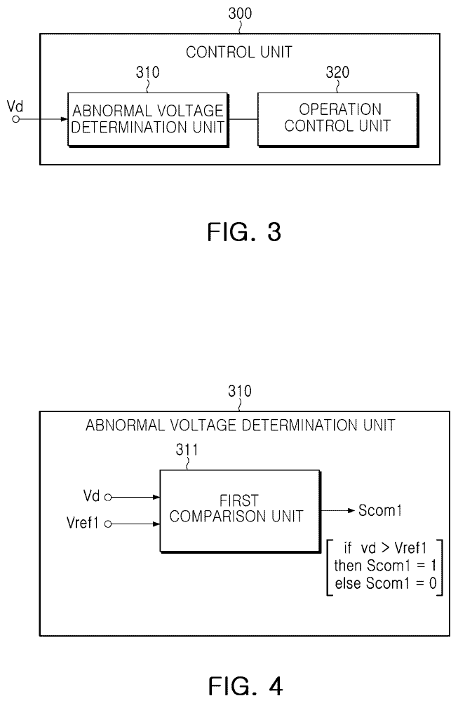

The control unit 300 determines whether the voltage between the neutral line LN and the ground line LG is abnormal based on the detection voltage Vd, and may control a predetermined operation when it is determined to be an abnormal voltage. This will be described with reference to FIGS. 3 to 9.

In FIG. 1, the device 10 for charging a battery may further include an output control unit 400, an alarm output unit 500, a power switch 600, and a power measurement unit 700, and the output control unit 400, the alarm output unit 500, the power switch 600, and the power measurement unit 700 of the device 10 for charging a battery will be described herein.

In the present disclosure, the voltage detection unit 100, the control unit 300, the output control unit 400, and the power measurement unit 700 may be respectively implemented as individual processors or may be implemented as an (e.g., one) integrated processor. The units and/or processors are not limited thereto.

In addition, the voltage detection unit 100, the control unit 300, the output control unit 400, and the power measurement unit 700 may be respectively implemented as hardware element(s) or software element(s) or a combination thereof in at least one integrated circuit (IC) built into the device 10 for charging a battery. The units, elements, and/or circuits are not limited thereto.

For example, the control unit 300 and the output control unit 400 may be included in a main board 40 of the device 10 for charging a battery. The units are not limited thereto.

For respective drawings of the present disclosure, redundant descriptions of components with the same symbols and functions may be omitted, and possible differences may be described.

FIG. 2 is a (e.g., user description) diagram for a device for charging a battery.

Referring to FIG. 2, the device 10 for charging a battery may receive AC power from a transformer 50 connected to a transmission tower 60 through multiple AC power lines L1, L2 and L3 and a neutral line LN of a power input terminal (Tinput, see FIG. 1), and the power input terminal (Tinput, see FIG. 1) of the device 10 for charging a battery may include a ground line LG connected to the ground for stable operation of the device 10 for charging a battery.

A charging gun CG of the device 10 for charging a battery may be plugged into an electric vehicle 5 to charge the battery of the electric vehicle 5.

FIG. 3 is an example diagram for a control unit.

Referring to FIG. 3, the control unit 300 may include an abnormal voltage determination unit 310 and an operation control unit 320.

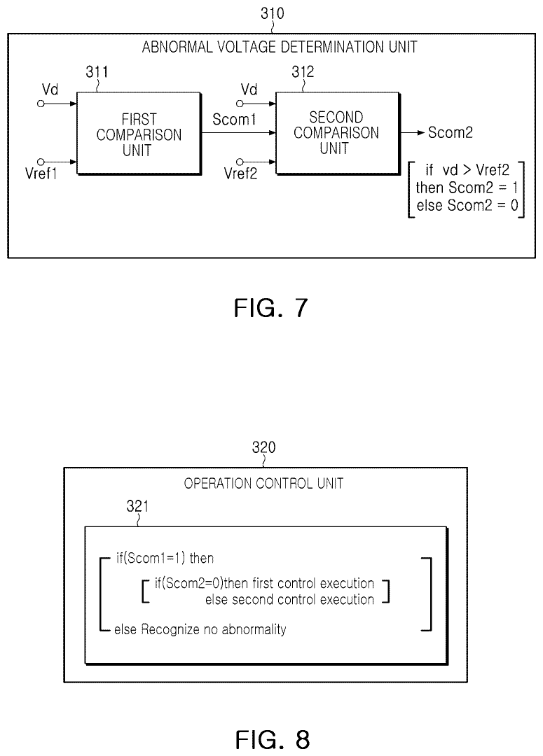

The abnormal voltage determination unit 310 may determine whether the voltage between the neutral line LN and the ground line LG is an abnormal voltage based on the detection voltage Vd received from the voltage detection unit 100. This will be described with reference to FIGS. 4 and 7.

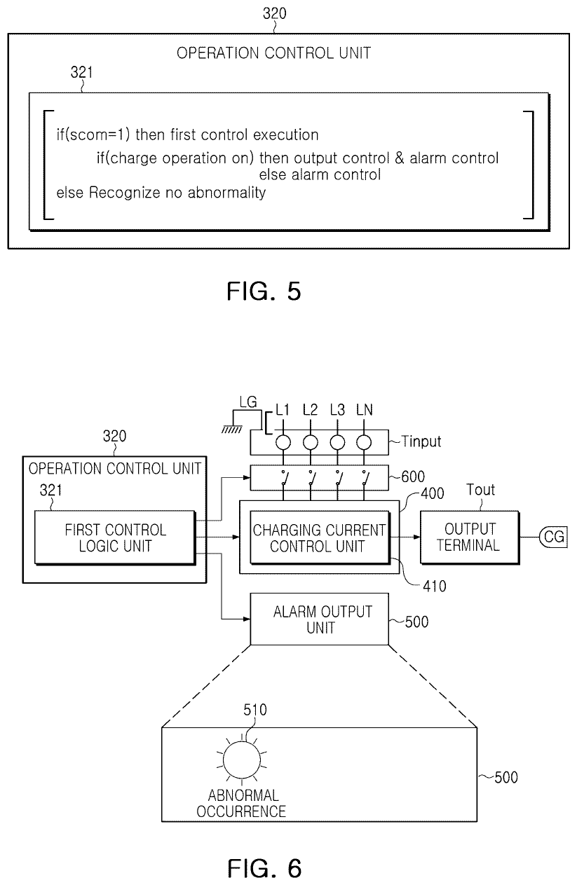

The operation control unit 320 may control a pre-determined operation when the voltage between the neutral line LN and the ground line LG is determined to be an abnormal voltage. This will be described with reference to FIGS. 5, 6, 8, and 9.

FIG. 4 is an example diagram for determining an abnormal voltage.

Referring to FIG. 4, the abnormal voltage determination unit 310 may include a first comparison unit 311.

For example, the first comparison unit 311 may compare the detection voltage Vd with a first reference voltage Vref1 and output a first comparison signal Scom1 having a level depending on whether the detection voltage Vd exceeds the first reference voltage Vref1.

For example, if the detection voltage Vd exceeds the first reference voltage Vref1, the first comparison signal Scom1 having a high level (e.g., logic ‘1’) may be output, and on the contrary, if the detection voltage Vd is lower than or equal to the first reference voltage Vref1, the first comparison signal Scom1 having a low level (e.g., logic ‘0’) may be output.

FIG. 5 is an example diagram for an operation control unit.

Referring to FIG. 5, the operation control unit 320 may include a first control logic unit 321.

For example, the first control logic unit 321 may perform (e.g., execute) the first control when the occurrence of the first-stage abnormality is determined based on the first comparison signal Scom1, and control the output control for charging and the abnormality occurrence alarm if the current charging operation is on, and control the alarm if the current charging operation is off.

For example, the first control logic unit 321 may control the output control unit 400 to adjust the magnitude of the charging current to a lower current (for example, 25 A) than a reference charging current (for example, 50 A). In addition, the first control logic unit 321 may control the alarm output unit 500 to light a corresponding lamp or corresponding LED to indicate the occurrence of an abnormal voltage, or control the corresponding content to be displayed on the corresponding display unit.

FIG. 6 is an example diagram for an output control unit and an alarm output unit.

Referring to FIG. 6, the device 10 for charging a battery may include an output control unit 400 and an alarm output unit 500.

The output control unit 400 may adjust the charging current according to the first control of the first control logic unit 321. For example, according to the control of the first control logic unit 321, the output control unit 400 may lower the charging current being charged to a lower current (for example, 25 A) than the current (for example, 50 A) and output the lowered current to the charging gun CG through an output terminal Tout.

The alarm output unit 500 may output an abnormality occurrence alarm notifying the occurrence of a first-stage abnormality according to the first control of the first control logic unit 321. For example, the alarm output unit 500 may include an abnormality occurrence alarm unit 510 for outputting an abnormality occurrence alarm, and the abnormality occurrence alarm unit 510 may include a lamp or a character display for indicating an abnormal occurrence.

FIG. 7 is an example diagram of an abnormal voltage determination unit.

Referring to FIG. 7, the abnormal voltage determination unit 310 may include a first comparison unit 311 and a second comparison unit 312.

The first comparison unit 311 may compare the detection voltage Vd with the first reference voltage Vref1 and output a first comparison signal Scom1 having a level depending on whether the detection voltage Vd exceeds the first reference voltage Vref1.

For example, if the detection voltage Vd exceeds the first reference voltage Vref1, a first comparison signal Scom1 having a high level (e.g., logic ‘1’) may be output, and on the contrary, if the detection voltage Vd is lower than or equal to the first reference voltage Vref1, a first comparison signal Scom1 having a low level (e.g., logic ‘0’) may be output.

The second comparison unit 312 may compare the detection voltage Vd with a second reference voltage Vref2 when the detection voltage Vd exceeds the first reference voltage Vref1, and output a second comparison signal Scom2 having a level depending on whether the detection voltage Vd exceeds the second reference voltage Vref2.

For example, if the detection voltage Vd exceeds the second reference voltage Vref2, a second comparison signal Scom2 having a high level (e.g., logic ‘1’) may be output, and on the contrary, if the detection voltage Vd is lower than or equal to the second reference voltage Vref2, a second comparison signal Scom2 having a low level (e.g., logic ‘0’) may be output.

In the present disclosure, the high level and the low level may be respectively logic 1 or logic 0, and the high level and the low level may be voltage levels, and are not limited thereto. In the above example, the case of active high is described, but this is an example for the convenience of explanation and understanding, and is not limited thereto, and thus, the present disclosure may also be applied to the case of active low.

FIG. 8 is an example of the operation control unit.

Referring to FIG. 8, the operation control unit 320 may include a second control logic unit 322.

For example, if the occurrence of a first-stage abnormality is determined based on the first comparison signal Scom1 and the second comparison signal Scom2, the second control logic unit 322 may perform a first control to control output control and an abnormality occurrence alarm if the current charging operation is on, and to control an alarm if the current charging operation is off.

For example, if the occurrence of a first-stage abnormality is determined, the second control logic unit 322 may control the output control unit 400 to control the magnitude of the charging current to be a lower current (for example, 25 A) than the reference charging current (for example, 50 A). In addition, the second control logic unit 322 may control the corresponding lamp or corresponding LED to light up to indicate the occurrence of an abnormal voltage in the alarm output unit 500, or control the corresponding content to be displayed on the corresponding display unit.

In addition, the second control logic unit 322 may perform a second control to control the charging operation to be stopped if the current charging operation is on, or to control the unusable alarm if the current charging operation is off, if the occurrence of the second-stage abnormality is determined based on the first comparison signal Scom1 and the second comparison signal Scom2.

For example, if the occurrence of the second-stage abnormality is determined, the second control logic unit 322 may control the power switch 600 (see FIG. 1) to be off to stop the charging operation. In addition, the second control logic unit 322 may control the corresponding lamp or corresponding LED to light up to indicate ‘unusable’ in the alarm output unit 500, or control the corresponding content, ‘unusable’, to be displayed on the corresponding display unit.

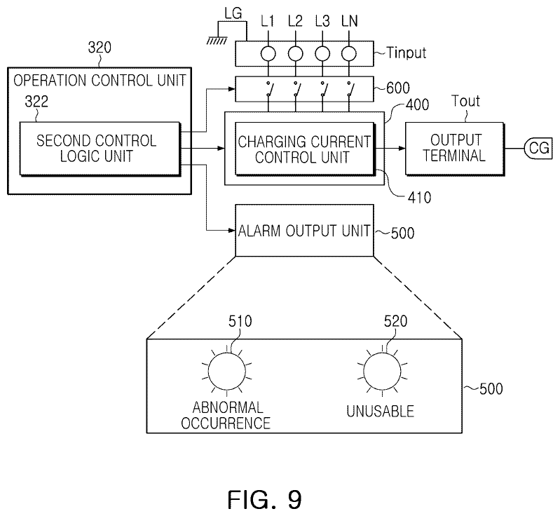

FIG. 9 is another example of an output control unit and an alarm output unit.

Referring to FIG. 9, a device 10 for charging a battery may include a power switch 600, an output control unit 400, and an alarm output unit 500.

The power switch 600 may switch the power line connected to the power input terminal Tinput to an off state according to the second control of the second control logic unit 322. For example, the power switch 600 may be connected to the control unit 300 through a second signal line (e.g., SL3, see FIG. 1) for receiving control. For example, the power switch 600 may be configured as a relay in the form of a contact switch that may be adjusted to an on state or an off state, but this is an example and is not limited thereto.

The output control unit 400 may control the charging current according to the second control of the second control logic unit 322. For example, the output control unit 400 may include a charging current control unit 410. The charging current control unit 410 may control the charging current for the AC power input from the power switch 600. For example, when the power switch 600 is in the off state, the charging current control unit 410 cannot output the charging current.

In addition, the alarm output unit 500 may output an unusable alarm 520 notifying the occurrence of a second-stage abnormality according to the second control of the second control logic unit 322. For example, the alarm output unit 500 may be connected to the control unit 300 through the third signal line (e.g., SL3, see FIG. 1) to receive control.

Meanwhile, the power measurement unit 700 connected between the power switch 600 and the output control unit 400 may be connected to the control unit 300 via a fourth signal line (e.g., SL4, see FIG. 1) for transmitting a measured value.

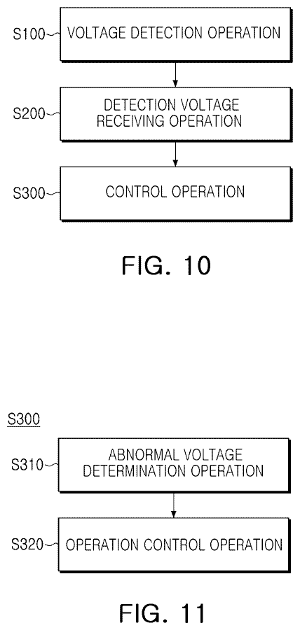

Hereinafter, a method of charging a battery will be described with reference to FIGS. 10 to 15. In this disclosure, the description of the method of charging a battery and the description of the device for charging a battery may be complementary unless there are mutually exclusive circumstances. Accordingly, overlapping descriptions may be omitted. Hereinafter, the (e.g., main) process of a method of charging a battery will be described.

FIG. 10 is a flow chart illustrating a method of charging a battery according to an embodiment.

Referring to FIG. 1 and FIG. 10, a method of charging a battery according to an embodiment may be performed by, for example, a device 10 for charging a battery.

The method of charging a battery may include a voltage detection operation (S100), a detection voltage receiving operation (S200), and a control operation (S300).

In the voltage detection operation (S100), the device 10 for charging a battery (see FIG. 1) may detect a voltage between a neutral line LN and a ground line LG included in a power input terminal Tinput for receiving AC power using a plurality of AC power lines L1, L2 and L3 and a neutral line LN, and may generate a detection voltage Vd.

In the detection voltage receiving operation (S200), the device 10 for charging a battery (see FIG. 1) may receive the detection voltage Vd from the voltage detection unit 200.

Then, in the control operation (S300), the device 10 for charging a battery (see FIG. 1) may determine whether the voltage between the neutral line LN and the ground line LG is abnormal based on the detection voltage Vd, and control a predetermined operation when the voltage is determined to be abnormal.

FIG. 11 is an example diagram for the control operation.

Referring to FIG. 11, the control operation (S300) may include an abnormal voltage determination operation (S310) and an operation control operation (S320).

In the abnormal voltage determination operation (S310), the device 10 for charging a battery (see FIG. 1) may determine whether the voltage between the neutral line LN and the ground line LG is an abnormal voltage based on the detection voltage Vd.

In the operation control operation (S320), the device 10 for charging a battery (see FIG. 1) may control a predetermined operation if the voltage between the neutral line LN and the ground line LG is determined to be an abnormal voltage.

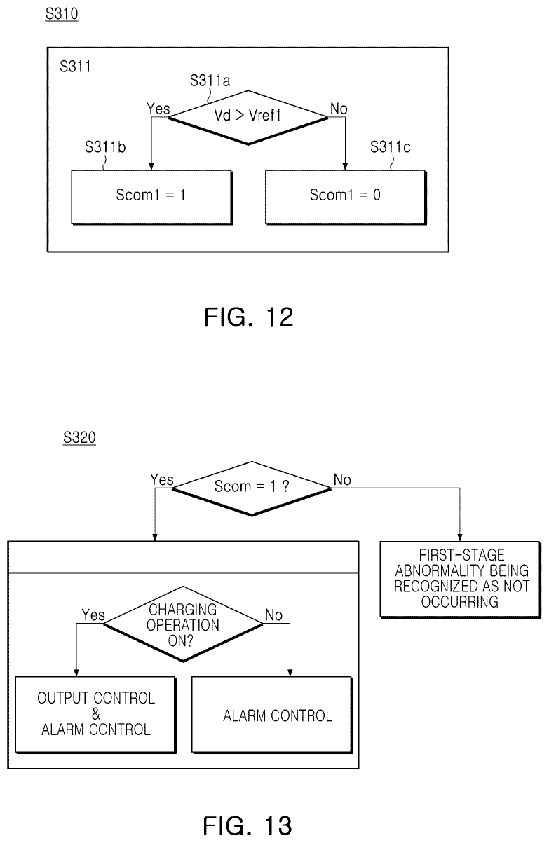

FIG. 12 is an example diagram of the abnormal voltage determination operation.

Referring to FIG. 12, the abnormal voltage determination operation (S310) may include a first comparison operation (S311).

In the first comparison operation (S311), the device 10 for charging a battery (see FIG. 1) may, for example, compare the detection voltage Vd with the first reference voltage Vref1 (S311a) and output a first comparison signal Scom1 having a level depending on whether the detection voltage Vd exceeds the first reference voltage Vref1 (S311b, S311c).

FIG. 13 is an example diagram for the operation control operation.

Referring to FIG. 13, the operation control operation (S320) may include a first control operation (S321).

In the first control operation (S321), if the occurrence of a first-stage abnormality is determined based on the first comparison signal Scom1, for example, the device 10 for charging a battery (see FIG. 1) may perform a first control, control output control and an alarm for notifying the occurrence of an abnormality when the current charging operation is on, and control an alarm for notifying the occurrence of an abnormality when the current charging operation is off.

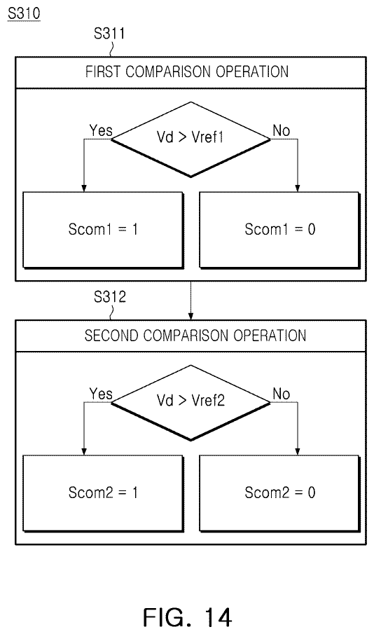

FIG. 14 is an example diagram for the abnormal voltage determination operation.

Referring to FIG. 14, the abnormal voltage determination operation (S310) may include a first comparison operation (S311) and a second comparison operation (S312).

In the first comparison operation (S311), the device 10 for charging a battery (see FIG. 1) may compare the detection voltage Vd with the first reference voltage Vref1 and output a first comparison signal Scom1 having a level depending on whether the detection voltage Vd exceeds the first reference voltage Vref1.

In addition, in the second comparison operation (S312), for example, when the detection voltage Vd exceeds the first reference voltage Vref1, the device 10 for charging a battery (see FIG. 1) may compare the detection voltage Vd with the second reference voltage Vref2 and output a second comparison signal Scom2 having a level depending on whether the detection voltage Vd exceeds the second reference voltage Vref2.

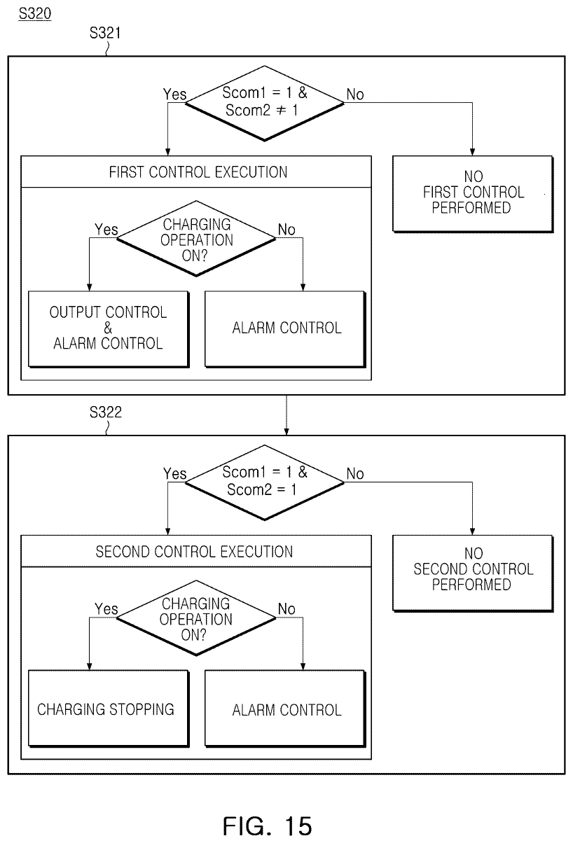

FIG. 15 is an example diagram for an operation control operation.

Referring to FIG. 15, the operation control operation (S320) may include a first control operation (S321) and a second control operation (S322).

In the first control operation (S321), if the occurrence of a first-stage abnormality is determined based on the first comparison signal Scom1 and the second comparison signal Scom2, the device 10 for charging a battery (see FIG. 1) may perform a first control to control output adjustment and an abnormality occurrence alarm if the current charging operation is on, and to control an alarm if the current charging operation is off.

In the second control operation (S322), if the occurrence of a second-stage abnormality is determined based on the first comparison signal Scom1 and the second comparison signal Scom2, the device 10 for charging a battery (see FIG. 1) may perform a second control to control the stopping of the charging operation when the current charging operation is on, and to control an unusable alarm when the current charging operation is off.

As set forth herein, according to an embodiment, a voltage between a neutral line on an input power side and the ground is detected, and based thereon, if an abnormal voltage occurs between the neutral line and the ground, a predetermined operation may be controlled, and further, if an abnormal voltage occurs between the neutral line and ground, various (e.g., different) predetermined operations may be controlled according to (e.g., a magnitude of) the abnormal voltage.

Accordingly, failure and malfunction may be prevented, and securing stability and convenience of use of a charging device may be provided.

While example embodiments have been shown and described above, it will be apparent to those skilled in the art that modifications and variations could be made without departing from the scope of the present disclosure as provided in the claims.

What is claimed is:

1. A device for charging a battery, comprising:
a power input terminal including a plurality of alternating current (AC) power lines, a neutral line, and a ground line;
a voltage detection unit detecting a voltage between the neutral line and the ground line and outputting a detection voltage; and
a control unit configured to determine whether the voltage between the neutral line and the ground line is abnormal based on the detection voltage, and configured to control a predetermined operation when the voltage is determined to be abnormal.

2. The device of claim 1, wherein the control unit includes:
an abnormal voltage determination unit configured to determine whether the voltage between the neutral line and the ground line is an abnormal voltage based on the detection voltage; and
an operation control unit configured to control the predetermined operation when the voltage between the neutral line and the ground line is determined to be an abnormal voltage.

3. The device of claim 2, wherein the abnormal voltage determination unit includes a first comparison unit configured to compare the detection voltage with a first reference voltage and output a first comparison signal having a level, wherein the level depends on whether the detection voltage exceeds the first reference voltage.

4. The device of claim 3, wherein the operation control unit includes a first control logic unit and wherein, when an occurrence of a first-stage abnormality is determined based on the first comparison signal, the first control logic unit is configured to perform a first control of
controlling output control for charging and controlling an abnormality occurrence alarm when a current charging operation is on, and
controlling an alarm when the current charging operation is off.

5. The device of claim 4, further comprising:
an output control unit configured to control a charging current according to the first control of the first control logic unit.

6. The device of claim 4, further comprising:
an alarm output unit configured to output the abnormality occurrence alarm notifying the occurrence of the first-stage abnormality according to the first control of the first control logic unit.

7. The device of claim 2, wherein the abnormal voltage determination unit includes
a first comparison unit configured to compare the detection voltage with a first reference voltage and output a first comparison signal having a level, wherein the level depends on whether the detection voltage exceeds the first reference voltage.

8. The device of claim 7, wherein the abnormal voltage determination unit includes a second comparison unit configured to compare the detection voltage with a second reference voltage when the detection voltage exceeds the first reference voltage and output a second comparison signal having a level, wherein the level depends on whether the detection voltage exceeds the second reference voltage.

9. The device of claim 8, wherein the operation control unit includes a second control logic unit, and wherein,
when an occurrence of a first-stage abnormality is determined based on the first comparison signal and the second comparison signal, the second control logic unit is configured to
perform a first control of controlling output control and an abnormality occurrence alarm when a current charging operation is on, and
control an alarm when the current charging operation is off.

10. The device of claim 9, wherein the operation control unit includes a second control logic unit, and wherein,
when an occurrence of a second-stage abnormality is determined based on the first comparison signal and the second comparison signal, the second control logic unit is configured to
perform a second control of controlling stopping of a charging operation when the current charging operation is on, and
control an unusable alarm when the current charging operation is off.

11. The device of claim 10, further comprising
a power switch configured to switch a power line connected to the power input terminal to an off state according to the second control of the second control logic unit.

12. The device of claim 10, further comprising
an output control unit configured to control a charging current according to the second control of the second control logic unit.

13. The device of claim 10, further comprising
an alarm output unit configured to output an unusable alarm notifying the occurrence of the second-stage abnormality according to the second control of the second control logic unit.

14. A method of charging a battery, comprising:
detecting a voltage via a voltage detection unit between a neutral line and a ground line included in a power input terminal for receiving AC power using a plurality of AC power lines and the neutral line, and generating a detection voltage;
receiving the detection voltage from the voltage detection unit;
determining via a control unit whether the voltage between the neutral line and the ground line is abnormal based on the detection voltage, and
controlling via the control unit a predetermined operation of charging the battery when the voltage is determined to be abnormal.

15. The method of charging the battery of claim 14, wherein the determining whether the voltage between the neutral line and the ground line is abnormal voltage includes:
comparing the detection voltage with a first reference voltage; and
outputting a first comparison signal having a level, wherein the level depends on whether the detection voltage exceeds the first reference voltage.

16. The method of charging the battery of claim 15, wherein controlling the predetermined operation includes:
performing a first control when an occurrence of a first-stage abnormality is determined based on the first comparison signal;
controlling output control and an abnormality occurrence alarm when a current charging operation is on; and
controlling an alarm when the current charging operation is off.

17. The method of charging the battery of claim 16, wherein the determining the abnormal voltage includes:
comparing the detection voltage with the first reference voltage; and
outputting the first comparison signal having a level depending on whether the detection voltage exceeds the first reference voltage.

18. The method of charging the battery of claim 17, wherein the determining the abnormal voltage further includes:
comparing the detection voltage with a second reference voltage; and
outputting a second comparison signal having a level depending on whether the detection voltage exceeds the second reference voltage, when the detection voltage exceeds the first reference voltage.

19. The method of charging the battery of claim 14, wherein controlling the predetermined operation includes:
performing a first control for controlling output control and an abnormality occurrence alarm when a current charging operation is on; and
controlling an alarm when the current charging operation is off, when an occurrence of a first-stage abnormality is determined based on the first comparison signal and the second comparison signal.

20. The method of charging the battery of claim 19, wherein controlling the predetermined operation further includes:
performing a second control for controlling stopping a charging operation when the current charging operation is on, and
controlling an unusable alarm when the current charging operation is off, when an occurrence of a second-stage abnormality is determined based on the first comparison signal and the second comparison signal.
